(19) United States
(12) Patent Application Publication
(10) Pub. No.: US 2026/0314177 A1
(43) Pub. Date: Oct. 8, 2026

(54) DISPLAY DEVICE, AND ELECTRONIC DEVICE USING THE SAME

(71) Applicant: Samsung Display Co., Ltd., Yongin-si (KR)

(72) Inventor: Jong Hyun CHOI, Yongin-si (KR)

(21) Appl. No.: 19/383,216

(22) Filed: Nov. 7, 2025

(30) Foreign Application Priority Data
Apr. 8, 2025 (KR) 10-2025-0045072

(51) Int. Cl. H10K 59/121; H10K 59/122

(52) U.S. Cl. CPC H10K 59/1213; H10K 59/122

(57) ABSTRACT

A display device includes: a substrate including a light emitting area and a non-light emitting area; a first gate conductive layer and a second gate conductive layer on the substrate and sequentially stacked; a third gate conductive layer on the second gate conductive layer and in contact with at least one of the first gate conductive layer or the second gate conductive layer through a gate contact hole; an interlayer insulating layer on the third gate conductive layer; a source-drain conductive layer on the interlayer insulating layer; a gate flat layer between the interlayer insulating layer and the source-drain conductive layer and located in the gate contact hole; and a passivation layer on the source-drain conductive layer, wherein the gate flat layer has an organic pattern shape, and wherein, in a portion overlapping the gate contact hole, the source-drain conductive layer overlaps the gate flat layer.

### CROSS-REFERENCE TO RELATED APPLICATION

This application claims priority to and the benefit of Korean Patent Application No. 10-2025-0045072, filed on Apr. 8, 2025, in the Korean Intellectual Property Office, the entire disclosure of which is incorporated by reference herein.

### BACKGROUND

### 1. Field

The present disclosure relates to a display device and an electronic device using the same.

### 2. Description of the Related Art

As an information society develops, the demand for a display device for displaying an image is increasing in various forms. The display devices may be flat display devices such as a liquid crystal display (LCD), a field emission display (FED), and a light emitting display (LED). The light emitting display may include an organic light emitting display device including an organic light emitting element, an inorganic light emitting display device including an inorganic light emitting element such as an inorganic semiconductor, and a micro or nano light emitting display device including a micro or nano light emitting element.

Recently, as the display device is applied to various devices, a display device applicable to high-resolution electronic devices is required. Accordingly, a plurality of conductive layers included in a thin film transistor layer of the display device may be stacked and disposed within a narrow area.

In addition, as the display device is applied to various devices, a display device with high heat-resistant reliability is required. Accordingly, a structure that reduced or minimizes an organic film is being applied to the thin film transistor layer of the display device.

### SUMMARY

Aspects and features of embodiments of the present disclosure provide a display device that is applicable to high-resolution electronic devices and has high heat-resistant reliability.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

The details of other embodiments are included in the detailed description and drawings.

According to one or more embodiments of the present disclosure, a display device includes: a substrate including a light emitting area and a non-light emitting area; a first gate conductive layer and a second gate conductive layer on the substrate and sequentially stacked; a third gate conductive layer on the second gate conductive layer and in contact with at least one of the first gate conductive layer or the second gate conductive layer through a gate contact hole; an interlayer insulating layer on the third gate conductive layer; a source-drain conductive layer on the interlayer insulating layer; a gate flat layer between the interlayer insulating layer and the source-drain conductive layer and located in the gate contact hole; and a passivation layer on the source-drain conductive layer, wherein the gate flat layer has an organic pattern shape, and wherein, in a portion overlapping the gate contact hole, the source-drain conductive layer overlaps the gate flat layer.

In one or more embodiments, the display device further includes: a via layer on the passivation layer and defining a via opening; a light emitting element on the via layer, the light emitting element including an anode electrode, a light emitting layer, and a cathode electrode; and a pixel defining layer on the anode electrode and defining a light emitting opening defining the light emitting area and the non-light emitting area, wherein, in a portion overlapping the light emitting opening, the anode electrode is in contact with the light emitting layer, and wherein, in a portion overlapping the via opening, the passivation layer is exposed.

In one or more embodiments, the light emitting opening and the via opening are spaced from each other, wherein the pixel defining layer does not overlap the via opening, and wherein the pixel defining layer has an organic pattern shape.

In one or more embodiments, the gate flat layer and the third gate conductive layer overlapping the gate contact hole overlap the via opening.

In one or more embodiments, the source-drain conductive layer includes a first source-drain conductive layer and a second source-drain conductive layer that are sequentially stacked, and wherein, in a plan view, the first source-drain conductive layer and the second source-drain conductive layer overlap the gate contact hole.

In one or more embodiments, the gate flat layer is in contact with the first source-drain conductive layer, and wherein the gate flat layer is entirely surrounded by the interlayer insulating layer and the first source-drain conductive layer.

In one or more embodiments, the first source-drain conductive layer includes at least one of a data connection electrode, a power line, or a connection electrode.

In one or more embodiments, the passivation layer includes: a first passivation layer located between the gate flat layer and the second source-drain conductive layer; and a second passivation layer covering the second source-drain conductive layer, wherein the gate flat layer is in contact with the interlayer insulating layer and the first passivation layer, and wherein the gate flat layer is entirely surrounded by the interlayer insulating layer and the first passivation layer.

In one or more embodiments, the second source-drain conductive layer includes at least one of a data electrode or a power line.

In one or more embodiments, the first passivation layer and the second passivation layer include an inorganic insulating material.

In one or more embodiments, the display device further includes: a first semiconductor layer located between the substrate and the first gate conductive layer and including a source region, a channel region, and a drain region; and a second semiconductor layer located between the second gate conductive layer and the third gate conductive layer, wherein the source-drain conductive layer is connected to at least one of the first semiconductor layer or the second semiconductor layer.

In one or more embodiments, the first semiconductor layer includes polysilicon, and wherein the second semiconductor layer includes an oxide semiconductor.

In one or more embodiments, in the portion overlapping the gate contact hole, the interlayer insulating layer includes a step difference, and a thickness of the gate flat layer is greater than or equal to a height of the step difference in the interlayer insulating layer.

In one or more embodiments, the gate flat layer is spaced from the third gate conductive layer, and wherein the gate flat layer is in contact with and covers a portion of an upper surface of the interlayer insulating layer facing the source-drain conductive layer.

In one or more embodiments, an electronic device includes: at least one display device including a substrate including a light emitting area and a non-light emitting area; and at least one of a display module, a processor, a memory, or a power module connected to the display device, wherein the display device includes: a first gate conductive layer and a second gate conductive layer on the substrate and sequentially stacked; a third gate conductive layer on the second gate conductive layer and in contact with at least one of the first gate conductive layer or the second gate conductive layer through a gate contact hole; an interlayer insulating layer on the third gate conductive layer; a source-drain conductive layer on the interlayer insulating layer; a gate flat layer between the interlayer insulating layer and the source-drain conductive layer and located in the gate contact hole; and a passivation layer on the source-drain conductive layer, wherein the gate flat layer has an organic pattern shape, and wherein, in a portion overlapping the gate contact hole, the source-drain conductive layer overlaps the gate flat layer.

In one or more embodiments, the display device further includes: a via layer on the passivation layer and defining a via opening; a light emitting element on the via layer, the light emitting element including an anode electrode, a light emitting layer, and a cathode electrode; and a pixel defining layer on the via layer and defining a light emitting opening defining the light emitting area and the non-light emitting area, wherein, in a portion overlapping the light emitting opening, the anode electrode is in contact with the light emitting layer, and wherein, in a portion overlapping the via opening, the passivation layer is exposed.

In one or more embodiments, the gate flat layer and the third gate conductive layer overlapping the gate contact hole overlap the via opening.

In one or more embodiments, the source-drain conductive layer includes a first source-drain conductive layer and a second source-drain conductive layer that are sequentially stacked, and wherein, in a plan view, the first source-drain conductive layer and the second source-drain conductive layer overlap the gate contact hole.

In one or more embodiments, the gate flat layer is in contact with the first source-drain conductive layer, wherein the gate flat layer is entirely surrounded by the interlayer insulating layer and the first source-drain conductive layer, and wherein the first source-drain conductive layer includes at least one of a data connection electrode, a power line, or a connection electrode.

In one or more embodiments, the passivation layer includes: a first passivation layer located between the gate flat layer and the second source-drain conductive layer; and a second passivation layer covering the second source-drain conductive layer, wherein the gate flat layer is in contact with the interlayer insulating layer and the first passivation layer, wherein the gate flat layer is entirely surrounded by the interlayer insulating layer and the first passivation layer, wherein the second source-drain conductive layer includes at least one of a data electrode or a power line, and wherein the first passivation layer and the second passivation layer include an inorganic insulating material.

The display device and the electronic device using the same according to one or more embodiments may include the organic via layer formed to define the via opening and the gate flat layer located in the gate contact hole in a portion overlapping the via opening. Furthermore, the display device and the electronic device using the same according to one or more embodiments may include the source-drain conductive layer overlapping the gate flat layer located in the gate contact hole. Accordingly, according to the display device and the electronic device using the same according to one or more embodiments, a display device that is applicable to a high-resolution electronic device and has high heat-resistant reliability may be provided.

However, effects, aspects, and features of embodiments are not restricted to the one set forth herein. The above and other effects, aspects, and features of embodiments will become more apparent to one of ordinary skill in the art to which embodiments pertain by referencing the claims.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a block diagram illustrating a display device according to one or more embodiments;

FIG. 3 is an equivalent circuit diagram illustrating a sub-pixel according to one or more embodiments;

FIG. 4 is a layout diagram of sub-pixels overlapping a display area according to one or more embodiments;

FIG. 5 is a layout diagram illustrating in detail an example of the equivalent circuit diagram of FIG. 3;

FIG. 6 is a cross-sectional view taken along the line X1-X1′ in FIG. 5;

FIG. 7 is a layout diagram illustrating in detail an example of a first semiconductor layer and a first gate conductive layer in FIG. 5;

FIG. 8 is a layout diagram illustrating in detail an example of a second gate conductive layer, a second semiconductor layer, and a third gate conductive layer in FIG. 5;

FIG. 9 is a layout diagram illustrating in detail an example of a first source-drain conductive layer and a second source-drain conductive layer in FIG. 5;

FIG. 10 is a cross-sectional view taken along the line X3-X3′ in FIG. 5;

FIG. 11 is an enlarged cross-sectional view of an area ‘A’ in FIG. 10;

FIG. 12 is an enlarged cross-sectional view of the area ‘A’ of FIG. 10 according to one or more other embodiments;

FIG. 13 is a cross-sectional view taken along the line X5-X5′ in FIG. 5;

FIG. 14 is a block diagram of an electronic device according to one or more embodiments; and

FIG. 15 illustrates schematic diagrams of electronic devices according to various embodiments.

### DETAILED DESCRIPTION

The present disclosure will now be described more fully herein with reference to the accompanying drawings, in which some embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present disclosure. Similarly, the second element could also be termed a first element.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

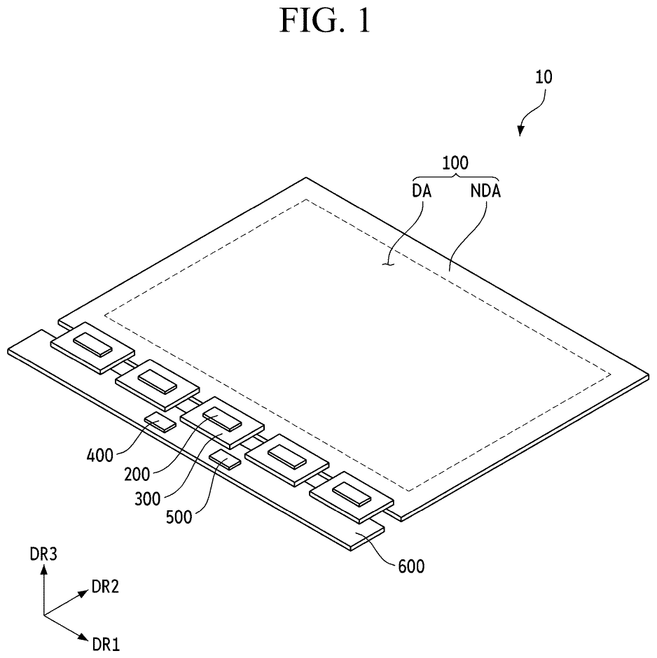

FIG. 1 is a perspective view illustrating a display device according to one or more embodiments.

Referring to FIG. 1, a display device 10 is a device that displays a moving image and/or a still image, and may be used as a display screen of each of various products such as televisions, laptop computers, monitors, billboards, and/or Internet of Things (IoT) as well as portable electronic devices such as mobile phones, smartphones, tablet personal computers (PCs), smartwatches, watch phones, mobile communication terminals, electronic organizers, electronic books, portable multimedia players (PMPs), navigation devices, and/or ultra mobile PCs (UMPCs).

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, and a micro or nano light emitting display device using a micro or nano light emitting diode (micro or nano LED). Hereinafter, it is mainly described that the display device 10 is the organic light emitting display device, but the present disclosure is not limited thereto.

The display device 10 may include a display panel 100, a plurality of source driving circuits 200, a plurality of flexible circuit boards 300, a timing control circuit (e.g., a timing controller) 400, a power supply circuit (e.g., a power supply unit) 500, and a circuit board 600.

The display panel 100 may be formed in a rectangular plane having long sides in a first direction DR1 and short sides in a second direction DR2 intersecting the first direction DR1. A corner where the long side in the first direction DR1 and the short side in the second direction DR2 meet may be rounded to have a curvature or may be formed at a right angle. The planar shape of the display panel 100 is not limited to the quadrangular shape, and may be formed in another polygonal, circular, or elliptical shape. The display panel 100 may be formed to be flat, but is not limited thereto. For example, the display panel 100 may include curved surface portions formed at left and right distal ends thereof and having a constant curvature or a variable curvature. In addition, the display panel 100 may be flexibly formed to be curved, bent, folded, and/or rolled.

The display panel 100 may include a display area DA that displays an image and a non-display area NDA disposed around the display area DA along an edge or a periphery of the display area DA.

The display area DA may occupy most of an area of the display panel 100. The display area DA may be disposed at a center of the display panel 100. A plurality of pixels may be disposed in the display area DA to display an image. The pixel will be described later.

The non-display area NDA may be an area that does not display an image. The non-display area NDA may be an edge area of the display panel 100. The non-display area NDA may be an area outside the display area DA. The non-display area NDA may be disposed to surround the display area DA.

Display pads may be disposed in the non-display area NDA to be connected to the plurality of flexible circuit boards 300. The display pads may be disposed at an edge on one side of the display panel 100.

Each of the source driving circuits 200 may be formed as an integrated circuit (IC) and attached to a corresponding flexible circuit board 300, but the present disclosure is not limited thereto. Each of the source driving circuits 200 may be attached onto the display panel 100 by a chip on glass (COG) method, a chip on plastic (COP) method, or an ultrasonic bonding method.

Each of the plurality of flexible circuit boards 300 may be disposed on the display pads disposed at the edge on one side of the display panel 100. Each of the plurality of flexible circuit boards 300 may be attached to the display pads using a conductive adhesive member such as an anisotropic conductive film. Accordingly, the plurality of flexible circuit boards 300 may be electrically connected to signal lines of the display panel 100. The plurality of flexible circuit boards 300 may be a flexible film such as a flexible printed circuit board (FPCB) or a chip on film (CoF).

The timing control circuit 400 may generate timing control signals for controlling the timing of a scan driving circuit, a light emitting driving circuit, and a source control circuit. The power supply circuit 500 may generate a plurality of power voltages for driving the display panel 100 according to input power input from the outside. Each of the timing control circuit 400 and the power supply circuit 500 may be formed as an integrated circuit (IC) and attached to the circuit board 600.

The circuit board 600 may be connected to one side of each of the plurality of flexible circuit boards 300. The circuit board 600 may be a rigid printed circuit board.

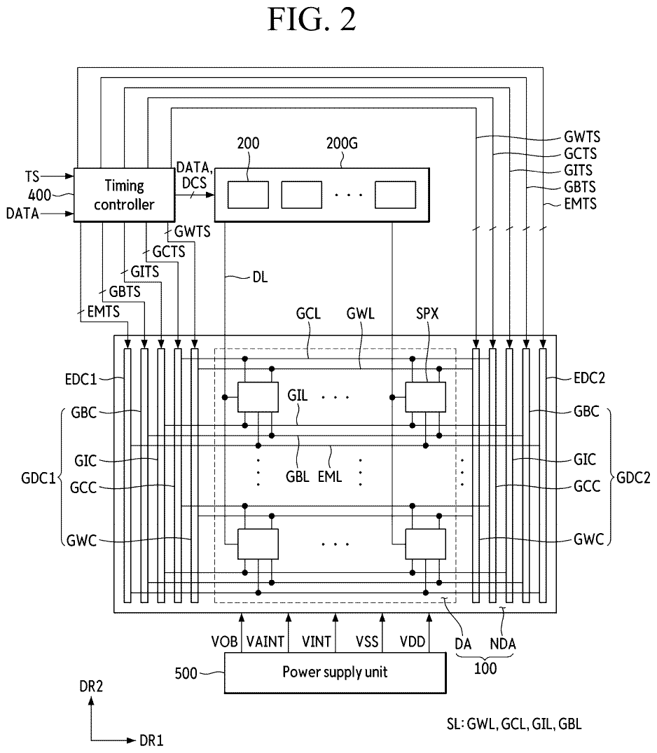

FIG. 2 is a block diagram illustrating the display device according to one or more embodiments.

Referring to FIG. 2, the display device 10 according to one or more embodiments may include a plurality of sub-pixels SPX, a plurality of scan lines SL, a plurality of emission control lines EML, and a plurality of data lines DL in a portion overlapping the display area DA. The plurality of scan lines SL may include a plurality of scan write lines GWL, a plurality of scan control lines GCL, a plurality of scan initialization lines GIL, and a plurality of bias scan lines GBL.

The plurality of sub-pixels SPX may be arranged in a matrix form along the first direction DR1 and the second direction DR2.

Each of the plurality of sub-pixels SPX may be connected to one of the plurality of scan write lines GWL, one of the plurality of scan control lines GCL, one of the plurality of scan initialization lines GIL, one of the plurality of bias scan lines GBL, one of the plurality of emission control lines EML, and one of the plurality of data lines DL.

Each of the plurality of sub-pixels SPX may receive a data voltage from the data line DL according to a scan write signal from the scan write line GWL, and may emit light from a light emitting element according to the data voltage.

The plurality of scan lines SL and the plurality of emission control lines EML may extend in the first direction DR1 and may be arranged along the second direction DR2. The plurality of data lines DL may extend in the second direction DR2 and may be arranged along the first direction DR1.

The display device 10 according to one or more embodiments may include a first scan driving circuit GDC1, a second scan driving circuit GDC2, a first light emitting driving circuit EDC1, and a second light emitting driving circuit EDC2 in a portion overlapping the non-display area NDA.

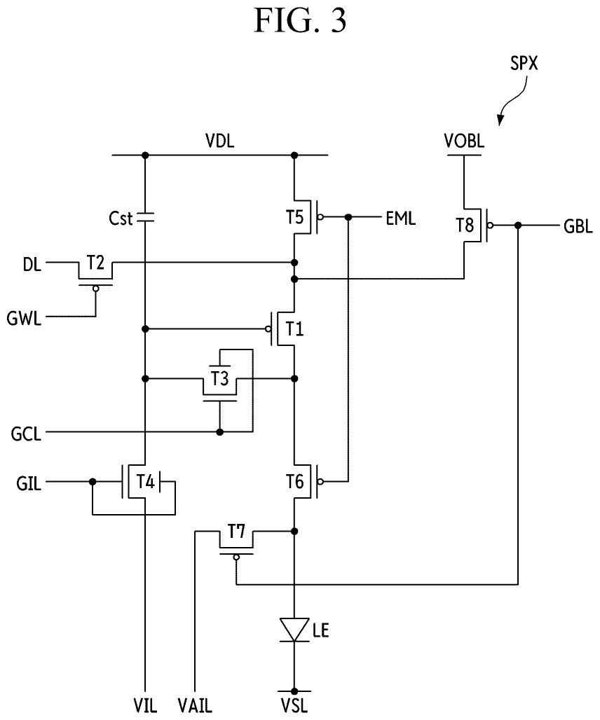

Each of the first scan driving circuit GDC1 and the second scan driving circuit GDC2 may include a scan write driving circuit GWC, a scan control driving circuit GCC, a scan initialization driving circuit GIC, and a bias scan driving circuit GBC. It is illustrated in FIG. 3 that the scan write driving circuit GWC, the scan control driving circuit GCC, the scan initialization driving circuit GIC, and the bias scan driving circuit GBC are disposed in order from the display area DA to the edge of the display panel 100, but the present disclosure is not limited thereto.

The scan write driving circuit GWC may receive a write timing signal GWTS from the timing control circuit 400. The scan write driving circuit GWC may generate scan write signals according to the write timing signal GWTS and sequentially output the scan write signals to the scan write lines GWL.

The scan control driving circuit GCC may receive a control timing signal GCTS from the timing control circuit 400. The scan control driving circuit GCC may generate scan control signals according to the control timing signal GCTS and sequentially output the scan control signals to the scan control lines GCL.

The scan initialization driving circuit GIC may receive an initialization timing signal GITS from the timing control circuit 400. The scan initialization driving circuit GIC may generate scan initialization signals according to the initialization timing signal GITS and sequentially output the scan initialization signals.

The bias scan driving circuit GBC may receive a bias timing signal GBTS from the timing control circuit 400. The bias scan driving circuit GBC may generate bias scan signals according to the bias timing signal GBTS and sequentially output the bias scan signals to the bias scan lines GBL.

Each of the first light emitting driving circuit EDC1 and the second light emitting driving circuit EDC2 may receive a light emitting timing signal EMTS from the timing control circuit 400. Each of the first light emitting driving circuit EDC1 and the second light emitting driving circuit EDC2 may generate emission control signals according to the light emitting timing signal EMTS and sequentially output the emission control signals to the emission control lines EML.

A data driving circuit 200G includes a plurality of source driving circuits 200. Each of the plurality of source driving circuits 200 may receive digital video data DATA and a data timing signal DCS from the timing control circuit 400. Each of the plurality of source driving circuits 200 converts the digital video data DATA into analog data voltages according to the data timing signal DCS and outputs the analog data voltages to the data lines DL. In this case, the sub-pixels SPX may be selected by the scan write signal, and the data voltages may be supplied to the selected sub-pixels SPX.

The timing control circuit 400 may receive digital video data DATA and timing signals TS from the outside. The timing control circuit 400 may generate a write timing signal GWTS, a control timing signal GCTS, an initialization timing signal GITS, a bias timing signal GBTS, and a light emitting timing signal EMTS according to the timing signals TS. The timing control circuit 400 may output the write timing signal GWTS to the scan write driving circuits GWC and output the control timing signal GCTS to the scan control driving circuits GCC. In addition, the timing control circuit 400 may output the initialization timing signal GITS to the scan initialization driving circuits GIC and output the bias timing signal GBTS to the bias scan driving circuits GBC. The timing control circuit 400 may output the light emitting timing signal EMTS to the first light emitting driving circuit EDC1 and the second light emitting driving circuit EDC2. In addition, the timing control circuit 400 may output the digital video data DATA and the data timing signals DCS to the source driving circuits 200.

The power supply circuit 500 may generate a plurality of panel driving voltages according to a power voltage from the outside. For example, the power supply circuit 500 may generate a first power voltage VSS, a second power voltage VDD, a third power voltage VINT, a fourth power voltage VAINT, and a fifth power voltage VOB and supply the generated power voltages to the display panel 100.

The first power voltage VSS may be a low potential voltage, and the second power voltage VDD may be a high potential voltage. The third power voltage VINT may be a first initialization voltage, the fourth power voltage VAINT may be a second initialization voltage, and the fifth power voltage VOB may be a third initialization voltage. The third power voltage VINT, the fourth power voltage VAINT, and the fifth power voltage VOB may be voltages higher than the first power voltage VSS and lower than the second power voltage VDD.

FIG. 3 is an equivalent circuit diagram illustrating a sub-pixel according to one or more embodiments.

Referring to FIG. 3 in addition to FIGS. 1 and 2, the sub-pixel SPX according to one or more embodiments may be connected to the scan write line GWL, the scan initialization line GIL, the scan control line GCL, the bias scan line GBL, the emission control line EML, and the data line DL.

The sub-pixel SPX according to one or more embodiments may include a first transistor T1 (e.g., a driving transistor), switching elements, a capacitor Cst, and a light emitting element LE. The switch elements include second to eighth transistors T2, T3, T4, T5, T6, T7, and T8.

The first transistor T1 controls a source-drain current (hereinafter referred to as a “driving current”) according to a data voltage applied to a gate electrode thereof. The gate electrode of the first transistor T1 may be connected to a second power line VDL to which the second power voltage VDD is applied.

The light emitting element LE may be an organic light emitting diode (OLED). The light emitting element LE emits light according to the driving current. Luminance of the light emitting element LE may be proportional to the driving current. A first electrode of the light emitting element LE may be connected to a first electrode of the seventh transistor T7 and a second electrode of the sixth transistor T6. A second electrode of the light emitting element LE may be connected to a first power line VSL to which the first power voltage VSS is applied. The first electrode of the light emitting element LE may be an anode electrode or a pixel electrode, and the second electrode thereof may be a cathode electrode.

The second transistor T2 is turned on by a scan write signal of a gate-on voltage applied to the scan write line GWL and connects the data line DL to the first electrode of the first transistor T1. As a result, the data voltage may be applied to the first electrode of the first transistor T1 during the period in which the second transistor T2 is turned on. A gate electrode of the second transistor T2 may be connected to the scan write line GWL, a first electrode thereof may be connected to the data line DL, and a second electrode thereof may be connected to the first electrode of the first transistor T1.

The third transistor T3 is turned on by a scan control signal of a gate-on voltage applied to the scan control line GCL and connects the gate electrode and the second electrode of the first transistor T1 to each other. As a result, the first transistor T1 may operate like a diode (e.g., the first transistor T1 may be diode-connected) during the period in which the third transistor T3 is turned on. A gate electrode of the third transistor T3 may be connected to the scan control line GCL, a first electrode thereof may be connected to the second electrode of the first transistor T1, and a second electrode thereof may be connected to the gate electrode of the first transistor T1.

The fourth transistor T4 is turned on by a scan initialization signal of a gate-on voltage applied to the scan initialization line GIL and connects the gate electrode of the first transistor T1 to a third power line VIL. During the period in which the fourth transistor T4 is turned on, the gate electrode of the first transistor T1 may be initialized to the third power voltage VINT from the third power line VIL. A gate electrode of the fourth transistor T4 may be connected to the scan initialization line GIL, a first electrode thereof may be connected to the gate electrode of the first transistor T1, and a second electrode thereof may be connected to the third power line VIL.

The fifth transistor T5 is turned on by an emission control signal of a gate-on voltage applied to the emission control line EML and connects the second power line VDL to the first electrode of the first transistor T1. During the period in which the fifth transistor T5 is turned on, the second power voltage (VDD in FIG. 3) of the second power line VDL may be applied to the first electrode of the first transistor T1. A gate electrode of the fifth transistor T5 may be connected to the emission control line EML, a first electrode thereof may be connected to the second power line VDL, and a second electrode thereof may be connected to the first electrode of the first transistor T1.

The sixth transistor T6 is turned on by an emission control signal of a gate-on voltage applied to the emission control line EML and connects the second electrode of the first transistor T1 to the first electrode of the light emitting element LE. During the period in which the sixth transistor T6 is turned on, the driving current of the first transistor T1 may be supplied to the light emitting element LE. A gate electrode of the sixth transistor T6 may be connected to the emission control line EML, a first electrode thereof may be connected to the second electrode of the first transistor T1, and a second electrode thereof may be connected to the first electrode of the light emitting element LE.

The seventh transistor T7 is turned on by a bias scan signal of a gate-on voltage applied to the bias scan line GBL and connects the first electrode of the light emitting element LE to a fourth power line VAIL. During the period in which the seventh transistor T7 is turned on, the first electrode of the light emitting element LE may be initialized to the fourth power voltage (VAINT in FIG. 3) from the fourth power line VAIL. A gate electrode of the seventh transistor T7 may be connected to the bias scan line GBL, a first electrode thereof may be connected to the first electrode of the light emitting element LE, and a second electrode thereof may be connected to the fourth power line VAIL.

The eighth transistor T8 is turned on by a bias scan signal of a gate-on voltage applied to the bias scan line GBL and connects the first electrode of the first transistor T1 to a fifth power line VOBL. During the period in which the eighth transistor T8 is turned on, the first electrode of the first transistor T1 may be initialized to the fifth power voltage (VOB in FIG. 3) from the fifth power line VOBL. A gate electrode of the eighth transistor T8 may be connected to the bias scan line GBL, a first electrode thereof may be connected to the first electrode of the first transistor T1, and a second electrode thereof may be connected to the fifth power line VOBL.

The capacitor Cst is formed between the gate electrode of the first transistor T1 and the second power line VDL. One electrode of the capacitor Cst may be connected to the gate electrode of the first transistor T1, and the other electrode thereof may be connected to the second power line VDL.

The first transistor T1, the second transistor T2, the fifth transistor T5, the sixth transistor T6, the seventh transistor T7, and the eighth transistor T8 may be formed as p-type metal oxide semiconductor field effect transistors (MOSFETs).

As an example, an active layer of each of the first transistor T1, the second transistor T2, the fifth transistor T5, the sixth transistor T6, the seventh transistor T7, and the eighth transistor T8 may include polysilicon. In addition, the first transistor T1, the second transistor T2, the fifth transistor T5, the sixth transistor T6, the seventh transistor T7, and the eighth transistor T8 may be turned on by a signal of a gate low voltage.

In addition, the third transistor T3 and the fourth transistor T4 may be formed as n-type metal oxide semiconductor field effect transistors (MOSFETs). In this case, an active layer of each of the third transistor T3 and the fourth transistor T4 may include an oxide semiconductor. In addition, the third transistor T3 and the fourth transistor T4 may be turned on by a signal of a gate high voltage.

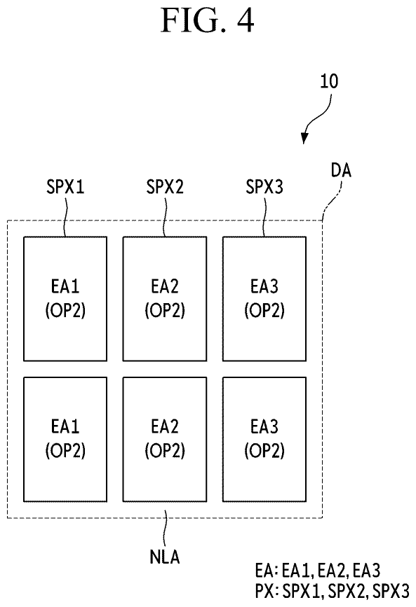

FIG. 4 is a layout diagram of sub-pixels overlapping a display area according to one or more embodiments.

Referring to FIG. 4, a pixel PX according to one or more embodiments may include a first sub-pixel SPX1, a second sub-pixel SPX2, and a third sub-pixel SPX3 positioned in a portion overlapping the display area DA. The first sub-pixel SPX1, the second sub-pixel SPX2, and the third sub-pixel SPX3 may be spaced (e.g., spaced apart) from each other.

The pixel PX may include a light emitting area EA. The light emitting area EA may be a portion from which light is emitted. As an example, the first sub-pixel SPX1 may include a first light emitting area EA1, the second sub-pixel SPX2 may include a second light emitting area EA2, and the third sub-pixel SPX3 may include a third light emitting area EA3.

In one or more embodiments, the first light emitting area EA1, the second light emitting area EA2, and third light emitting area EA3 may emit light of different colors. As an example, the first light emitting area EA1 may emit red light, the second light emitting area EA2 may emit green light, and the third light emitting area EA3 may emit blue light. However, the first light emitting area EA1, the second light emitting area EA2, and the third light emitting area EA3 are not limited thereto, and may also emit the same color depending on the embodiment.

The display device 10 according to one or more embodiments may include a non-light emitting area NLA in a portion overlapping the display area DA. The non-light emitting area NLA may be positioned to be around (e.g., to surround) each of the first to third light emitting areas EA1, EA2, and EA3 and may assist in preventing color mixing of light emitted from each of the first to third light emitting areas EA1, EA2, and EA3.

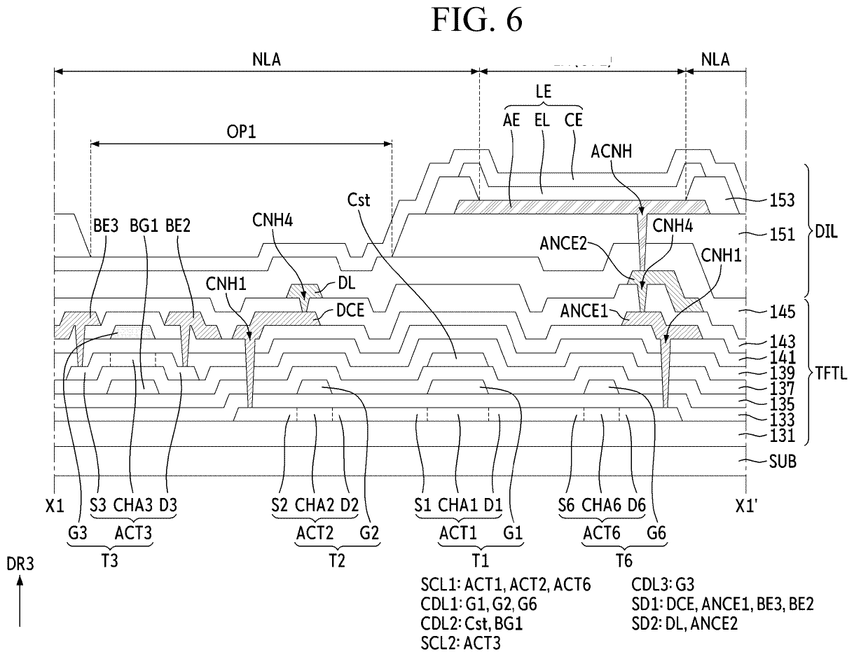

In one or more embodiments, the light emitting area EA and the non-light emitting area NLA may be defined by a light emitting opening OP2. The light emitting opening OP2 may be defined by a pixel defining layer (‘153’ in FIG. 6) described later.

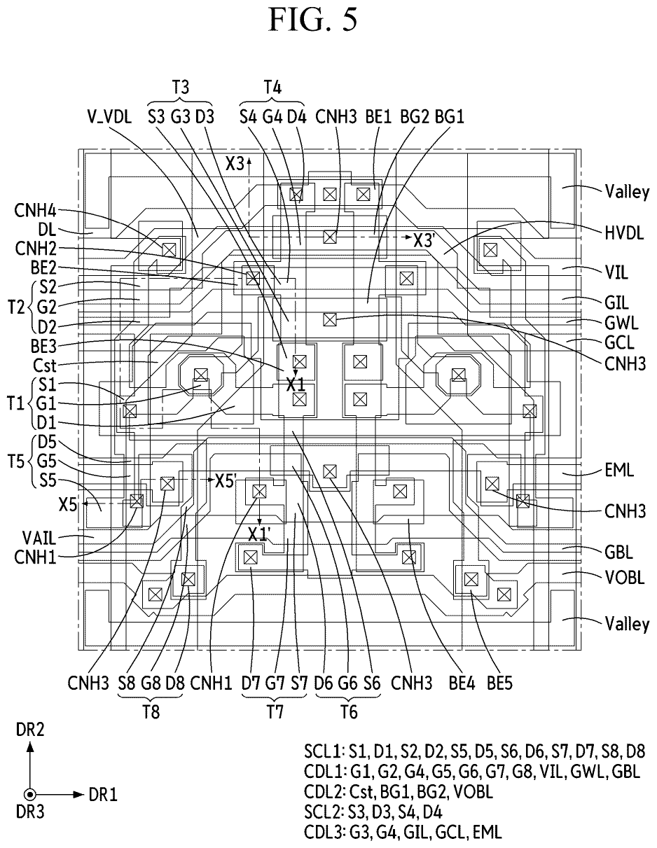

FIG. 5 is a layout diagram illustrating in detail an example of the equivalent circuit diagram of FIG. 3 and FIG. 6 is a cross-sectional view taken along the line X1-X1′ in FIG. 5.

Referring to FIGS. 5 and 6 in addition to FIG. 1-4, the display device 10 may include a substrate SUB, a thin film transistor layer TFTL, and a display element layer DIL stacked in a third direction DR3. The above-described plurality of first to eighth transistors T1 to T8 and the plurality of conductive lines may be positioned in the thin film transistor layer TFTL.

As illustrated in FIG. 5, in one or more embodiments, a gate electrode G1 of the first transistor T1 may be connected to a third drain region D3 of the third transistor T3 and a fourth source region S4 of the fourth transistor T4 through a second connection electrode BE2 penetrating through a first contact hole CNH2.

A first source region S1 of the first transistor T1 may be connected to a second drain region D2 of the second transistor T2, and a first drain region D1 of the first transistor T1 may be connected to a sixth source region S6 of the sixth transistor T6. In addition, the first drain region D1 of the first transistor T1 may be connected to a third source region S3 of the third transistor T3 through a third connection electrode BE3.

A gate electrode G2 of the second transistor T2 may be connected to the scan write line GWL extending in the first direction DR1, and a second source region S2 may be connected to a data connection electrode DCE through a first contact hole CNH1 (e.g., see FIG. 6). In addition, the data connection electrode DCE may be connected to the data line DL extending in the second direction DR2 through a source-drain contact hole CNH4. The second drain region D2 of the second transistor T2 may be connected to the first source region S1 of the first transistor T1.

A gate electrode G3 of the third transistor T3 may be connected to the scan control line GCL extending in the first direction DR1, a third source region S3 may be connected to the second drain region D2 of the first transistor T1 through a third connection electrode BE3, and a third drain region D3 may be connected to the gate electrode G1 of the first transistor T1 through the second connection electrode BE2.

A gate electrode G4 of the fourth transistor T4 may be connected to the scan initialization line GIL extending in the first direction DR1, and a fourth source region S4 may be connected to the gate electrode G1 of the first transistor T1 through a third connection electrode BE3. In addition, a fourth source region S4 may be connected to the third drain region D3. A fourth drain region D4 may be connected to the third power line VIL extending in the first direction DR1 and may be connected to a fourth drain region D4 of a neighboring sub-pixel through the first connection electrode BE1.

One electrode of the capacitor Cst may be connected to the gate electrode G1 of the first transistor T1, and the other electrode thereof may be connected to a second vertical power line V_VDL.

A gate electrode G5 of the fifth transistor T5 may be connected to the emission control line EML through a gate contact hole CNH3, and a fifth source region S5 may be connected to a second horizontal power line HVDL through the first contact hole CNH1. In addition, the fifth source region S5 may be connected to the second vertical power line V_VDL through the source-drain contact hole CNH4. A fifth drain region D5 may be connected to the first source region S1 of the first transistor T1.

A gate electrode G6 of the sixth transistor T6 may be connected to the emission control line EML, a sixth source region S6 may be connected to the first drain region D1 of the first transistor T1, and a sixth drain region D6 may be connected to an anode electrode AE of a light emitting element LE described later through the first contact hole CNH1.

A gate electrode G7 of the seventh transistor T7 may be connected to the bias scan line GBL extending in the first direction DR1, and a seventh source region S7 may be connected to the anode electrode AE of the light emitting element LE through the first contact hole CNH1. In addition, a seventh source region S7 may be connected to the sixth drain region D6. A seventh drain region D7 may be connected to the fourth power line VAIL extending in the first direction DR1 through the first contact hole CNH1.

A gate electrode G8 of the eighth transistor T8 may be connected to the bias scan line GBL, an eighth source region S8 may be connected to the first source region S1 of the first transistor T1, and an eighth drain region D8 may be connected to the fifth power line VOBL extending in the first direction DR1 through the first contact hole CNH1.

In one or more embodiments, in a plan view, the anode electrode AE of the light emitting element LE may be positioned in a portion overlapping the sixth drain region D6 of the sixth transistor T6, the seventh source region S7 of the seventh transistor T7, and the gate electrode G1 and the first drain region D1 of the first transistor T1.

As illustrated in FIG. 6, the substrate SUB may be a rigid substrate or be a flexible substrate that may be bent, folded, and/or rolled. The substrate SUB may include an insulating material such as glass, quartz, and/or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and/or a combination thereof. Alternatively, the substrate SUB may also include a metal material.

The thin film transistor layer TFTL may be positioned on the substrate SUB. The thin film transistor layer TFTL may include a plurality of insulating layers, a plurality of semiconductor layers, and a plurality of conductive layers.

As an example, the plurality of insulating layers included in the thin film transistor layer TFTL may include a buffer layer 131, a first gate insulating layer 133, a second gate insulating layer 135, a first interlayer insulating layer 137, a third gate insulating layer 139, a second interlayer insulating layer 141, a first passivation layer 143, and a second passivation layer 145.

The plurality of insulating layers included in the thin film transistor layer TFTL may include an inorganic insulating material. As an example, the inorganic insulating material may include silicon nitride (SiNx), silicon oxide nitride (SiON), silicon oxide (SiOx), titanium oxide (TiOx), and/or aluminum oxide (AlOx).

In addition, the thin film transistor TFTL according to one or more embodiments may include a first semiconductor layer SCL1, a first gate conductive layer CDL1, a second gate conductive layer CDL2, a second semiconductor layer SCL2, a third gate conductive layer CDL3, a first source-drain conductive layer SD1, and a second source-drain conductive layer SD2 that are sequentially stacked.

The buffer layer 131 according to one or more embodiments may be disposed on the substrate SUB. The buffer layer 131 may protect the conductive layers included in the thin film transistor layer TFTL from moisture permeating through the substrate SUB vulnerable to moisture permeation.

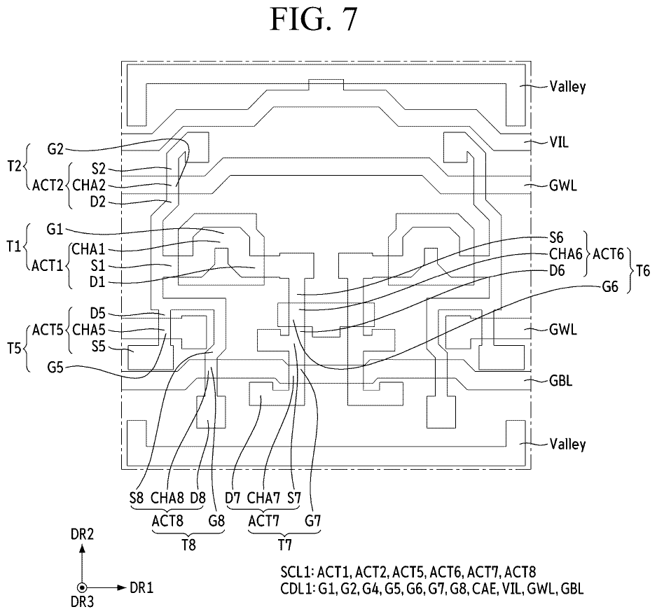

FIG. 7 is a layout diagram illustrating in detail an example of a first semiconductor layer and a first gate conductive layer in FIG. 5.

Referring to FIG. 5-7, the first semiconductor layer SCL1 may be located on the buffer layer 131. The first semiconductor layer SCL1 may include polysilicon such as polycrystalline silicon, single crystal silicon, low-temperature polycrystalline silicon, or amorphous silicon.

In one or more embodiments, the first semiconductor layer SCL1 may include a first active layer ACT1 of the first transistor T1, a second active layer ACT2 of the second transistor T2, a fifth active layer ACT5 of the fifth transistor T5, a sixth active layer ACT6 of the sixth transistor T6, a seventh active layer ACT7 of the seventh transistor T7, and an eighth active layer ACT8 of the eighth transistor T8.

The first active layer ACT1 may include a first channel region CHA1, a first source region S1, and a first drain region D1, and the first channel region CHA1 may overlap a gate electrode G1 included in the first gate conductive layer CDL1 in a third direction DR3 that is a thickness direction of the substrate SUB. In the present specification, the third direction DR3 may be defined as a thickness direction of the substrate SUB or a thickness direction of the display device 10.

The first source region S1 may be disposed on one side of the first channel region CHA1, and the first drain region D1 may be disposed on the other side of the first channel region CHA1. The first source region S1 and the first drain region D1 may be regions that do not overlap the gate electrode G1 in the third direction DR3. The first source region S1 and the first drain region D1 may be regions having conductivity by doping a semiconductor material with ions.

The second active layer ACT2 may include a second channel region CHA2, a second source region S2, and a second drain region D2. The second channel region CHA2 may be a region overlapping a gate electrode G2 in the third direction DR3 that is the thickness direction of the substrate SUB.

The second source region S2 may be disposed on one side of the second channel region CHA2, and the second drain region D2 may be disposed on the other side of the second channel region CHA2. The second source region S2 and the second drain region D2 may be regions that do not overlap the gate electrode G2 in the third direction DR3. The second source region S2 and the second drain region D2 may be regions having conductivity by doping a semiconductor material with ions.

The sixth active layer ACT6 may include a sixth channel region CHA6, a sixth source region S6, and a sixth drain region D6. The sixth channel region CHA6 may be a region overlapping a gate electrode G6 in the third direction DR3 that is the thickness direction of the substrate SUB.

The sixth source region S6 may be disposed on one side of the sixth channel region CHA6, and the sixth drain region D6 may be disposed on the other side of the sixth channel region CHA6. The sixth source region S6 and the sixth drain region D6 may be regions that do not overlap the gate electrode G6 in the third direction DR3. The sixth source region S6 and the sixth drain region D6 may be regions having conductivity by doping a semiconductor material with ions.

The fifth transistor T5, the seventh transistor T7, and the eighth transistor T8 may include substantially the same structures as the first transistor T1, the second transistor T2, and the third transistor T3. The redundant contents will be omitted.

The first gate insulating layer 133 may be located on the first semiconductor layer SCL1 and on the buffer layer 131. The first gate insulating layer 133 may entirely cover the first semiconductor layer SCL1 and the buffer layer 131.

The first gate conductive layer CDL1 may be positioned on the first gate insulating layer 133. The first gate conductive layer CDL1 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

In one or more embodiments, the first gate conductive layer CDL1 may include the gate electrodes included in each of the first transistor T1, the second transistor T2, the fifth transistor T5, the sixth transistor T6, the seventh transistor T7, and the eighth transistor T8.

In one or more embodiments, the gate electrode G1 of the first transistor T1 may overlap the first channel region CHA1 of the first transistor T1, the gate electrode G2 of the second transistor T2 may overlap the second channel region CHA2 of the second transistor T2, and the third gate electrode G3 of the third transistor T3 may overlap the third channel region CHA3 of the third transistor T3. The redundant contents will be omitted.

In addition, the first gate conductive layer CDL1 may include the third power line VIL, the scan write line GWL, and the bias scan line GBL. The third power line VIL, the scan write line GWL, and the bias scan line GBL may extend in the first direction DR1.

In one or more embodiments, the gate electrode G2 of the second transistor T2 may be connected to the scan write line GWL, and the gate electrode G7 of the seventh transistor T7 and the gate electrode G8 of the eighth transistor T8 may be connected to the bias scan line GBL.

The second gate insulating layer 135 may be positioned on the first gate conductive layer CDL1 and on the first gate insulating layer 133. The second gate insulating layer 135 may entirely cover the first gate conductive layer CDL1 and the first gate insulating layer 133.

Referring to FIG. 5-7, the display device 10 according to one or more embodiments may include valley areas Valley positioned on the periphery of the plurality of first to eighth transistors T1 to T8. The valley area Valley may be a portion where the first semiconductor layer SCL1 and the first gate conductive layer CDL1 do not overlap. It is illustrated in the drawings that the valley areas Valley face each other on one side and the other side of the second direction DR2, but the present disclosure is not limited thereto. Depending on the embodiment, the arrangement of the valley areas Valley may be variously changed.

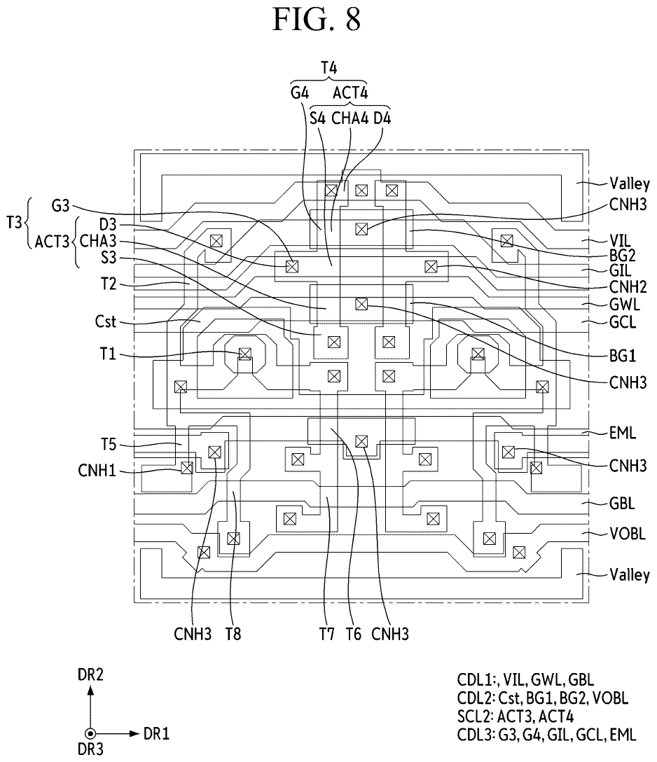

FIG. 8 is a layout diagram illustrating in detail an example of a second gate conductive layer, a second semiconductor layer, and a third gate conductive layer in FIG. 5. FIG. 8 illustrates a layout diagram in which a second gate conductive layer, a second semiconductor layer, and a third gate conductive layer are additionally formed on the layout of FIG. 7.

Referring to FIG. 5-8, a second gate conductive layer CDL2 may be positioned on the second gate insulating layer 135. The second gate conductive layer CDL2 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

In one or more embodiments, the second gate conductive layer CDL2 may include a capacitor Cst, a first lower electrode BG1, a second lower electrode BG2, and a fifth power line VOBL.

The capacitor Cst may overlap the gate electrode G1 of the first transistor T1. Because the second gate insulating layer 135 has a dielectric constant, a capacitor may be formed between the gate electrode G1 and the capacitor Cst.

The first lower electrode BG1 may be located in a portion overlapping the third channel region CHA3 of the third transistor T3 and the gate electrode G3 of the third transistor T3. The first lower electrode BG1 may be utilized as a back gate electrode to adjust the characteristics of the third transistor T3.

The second lower electrode BG2 may be positioned in a portion overlapping the fourth channel region CHA4 of the fourth transistor T4 and the gate electrode G4 of the fourth transistor T4. The second lower electrode BG2 may be utilized as a back gate electrode to adjust the characteristics of the fourth transistor T4.

The first interlayer insulating layer 137 may be positioned on the second gate conductive layer CDL2 and on the second gate insulating layer 135. The first interlayer insulating layer 137 may entirely cover the second gate conductive layer CDL2 and the second gate insulating layer 135.

The second semiconductor layer SCL2 may be located on the first interlayer insulating layer 137. The second semiconductor layer SCL2 may include an oxide semiconductor. For example, the second semiconductor layer SCL2 may include IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

In one or more embodiments, the second semiconductor layer SCL2 may include a third active layer ACT3 of the third transistor T3 and a fourth active layer ACT4 of the fourth transistor T4.

The third active layer ACT3 may include a third channel region CHA3, a third source region S3, and a third drain region D3, and the third channel region CHA3 may be a region overlapping the third gate electrode G3 included in the third gate conductive layer CDL3 and the first lower electrode BG1.

The third source region S3 may be disposed on one side of the third channel region CHA3, and the third drain region D3 may be disposed on the other side of the third channel region CHA3. The third source region S3 and the third drain region D3 may be regions that do not overlap the gate electrode G3 in the third direction DR3. The third source region S3 and the third drain region D3 may be regions having conductivity by doping a semiconductor material with ions.

The fourth active layer ACT4 may include a fourth channel region CHA4, a fourth source region S4, and a fourth drain region D4, and the fourth channel region CHA4 may be a region overlapping the gate electrode G4 included in the third gate conductive layer CDL3 and the second lower electrode BG2 (e.g., see FIG. 8).

The fourth source region S4 may be disposed on one side of the fourth channel region CHA4, and the fourth drain region D4 may be disposed on the other side of the fourth channel region CHA4. The fourth source region S4 and the fourth drain region D4 may be regions that do not overlap the gate electrode G4 in the third direction DR3. The fourth source region S4 and the fourth drain region D4 may be regions having conductivity by doping a semiconductor material with ions.

The third gate insulating layer 139 may be positioned on the second semiconductor layer SCL2 and on the first interlayer insulating layer 137. The third gate insulating layer 139 may entirely cover the second semiconductor layer SCL2 and the first interlayer insulating layer 137.

The third gate conductive layer CDL3 may be located on the third gate insulating layer 139. The third gate conductive layer CDL3 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

The third gate conductive layer CDL3 according to one or more embodiments may include a third gate electrode G3 of the third transistor T3 and a fourth gate electrode G4 of the fourth transistor T4. The third gate electrode G3 may overlap the third active layer ACT3 in the third direction DR3, and the fourth gate electrode G4 may overlap the fourth active layer ACT4 in the third direction DR3.

In addition, the third gate conductive layer CDL3 according to one or more embodiments may include a scan initialization line GIL extending in the first direction DR1, a scan control line GCL extending in the first direction DR1, and an emission control line EML extending in the first direction DR1. The redundant descriptions will be omitted.

The second interlayer insulating layer 141 may be located on the third gate conductive layer CDL3 and on the third gate insulating layer 139. The second interlayer insulating layer 141 may entirely cover the third gate conductive layer CDL3 and the third gate insulating layer 139.

In one or more embodiments, the second semiconductor layer SCL2 and the second gate conductive layer CDL2 may not overlap the valley area Valley.

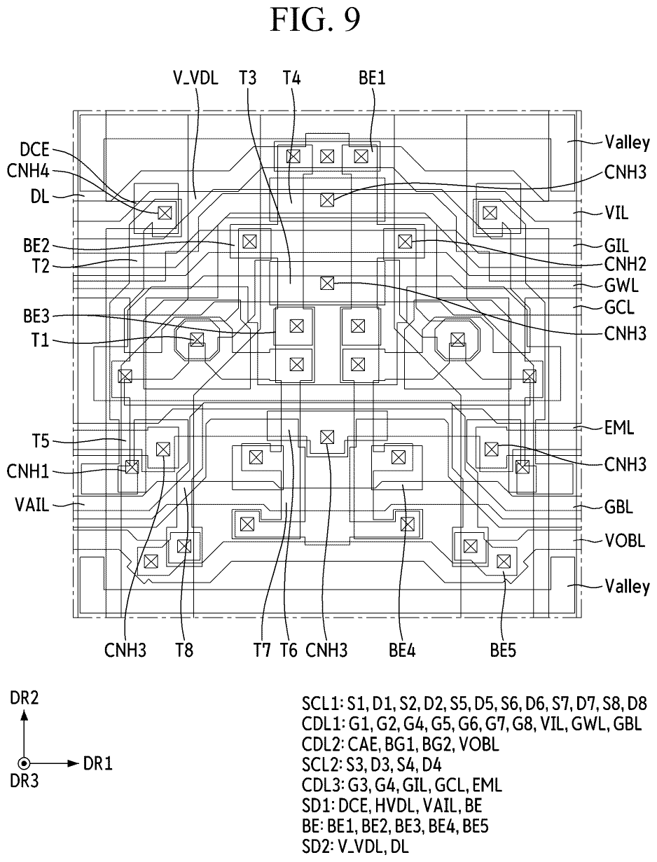

FIG. 9 is a layout diagram illustrating in detail an example of a first source-drain conductive layer and a second source-drain conductive layer in FIG. 5. FIG. 9 illustrates a layout diagram in which a first source-drain conductive layer and a second source-drain conductive layer are additionally formed on the layout of FIG. 8.

Referring to FIG. 5-9, a first source-drain conductive layer SD1 may be located on the second interlayer insulating layer 141. The first source-drain conductive layer SD1 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

In one or more embodiments, the first source-drain conductive layer SD1 may include a data connection electrode DCE, a first anode connection electrode (ANCE1 in FIG. 6), a fourth power line VAIL, a second horizontal power line HVDL, and a connection electrode BE.

The connection electrode BE may include first to fifth connection electrodes BE1, BE2, BE3, BE4, and BE5. The first connection electrode BE1 may connect the fourth drain region D4 included in each of the plurality of sub-pixels adjacent to each other. Each fourth drain region D4 may be connected to the first connection electrode BE1 through the second contact hole CNH2.

The second connection electrode BE2 may connect the third drain region D3 of the third transistor T3 and the gate electrode G1 of the first transistor T1. The third drain region D3 may be connected to the second connection electrode BE2 through the second contact hole CNH2, and the gate electrode G1 may be connected to the second connection electrode BE2 through the first contact hole CNH1.

The third connection electrode BE3 may connect the third source region S3 of the third transistor T3 and the first drain region D1 of the first transistor T1. The third source region S3 may be connected to the third connection electrode BE3 through the second contact hole CNH2, and the first drain region D1 may be connected to the third connection electrode BE3 through the first contact hole CNH1.

The fourth connection electrode BE4 may connect the sixth drain region D6 of the sixth transistor T6 and the seventh source region S7 of the seventh transistor T7 to the anode electrode AE through the first contact hole CNH1. That is, the fourth connection electrode BE4 may be the first anode connection electrode ANCE1.

The fifth connection electrode BE5 may connect the eighth drain region D8 of the eighth transistor T8 and the fifth power line VOBL. Each of the eighth drain region D8 and the fifth power line VOBL may be connected to the fifth connection electrode BE5 through the first contact hole CNH1.

The data connection electrode DCE may be electrically connected to the second source region S2 of the second transistor T2 through the first contact hole CNH1. In addition, the data connection electrode DCE may be connected to the data line DL through the source-drain contact hole CNH4.

The first anode connection electrode ANCE1 may be electrically connected to the sixth drain region D6 of the sixth transistor T6 through the first contact hole CNH1. In addition, the first anode connection electrode ANCE1 may be connected to a second anode connection electrode ANCE2 through the source-drain contact hole CNH4.

The fourth power line VAIL may be connected to the seventh drain region D7 of the seventh transistor T7 through the first contact hole CNH1. The fourth power line VAIL may overlap the emission control line EML and the bias scan line GBL in the third direction DR3. The fourth power line VAIL may be disposed to pass through a portion overlapping the third contact hole CNH3.

The second horizontal power line HVDL may be connected to the fifth source region S5 of the fifth transistor T5 through the first contact hole CNH1. The second horizontal power line HVDL may overlap the scan initialization line GIL, the scan control line GCL, and the scan write line GWL in the third direction DR3. The second horizontal power line HVDL may be disposed to pass through a portion overlapping the third contact hole CNH3.

The first passivation layer 143 may be located on the first source-drain conductive layer SD1 and on the second interlayer insulating layer 141. The first passivation layer 143 may entirely cover the first source-drain conductive layer SD1 and the second interlayer insulating layer 141.

In one or more embodiments, the first passivation layer 143 may include an inorganic insulating material. Details will be described later.

The second source-drain conductive layer SD2 may be located on the first passivation layer 143. The second source-drain conductive layer SD2 may be formed as a single layer or a multi-layer made of molybdenum (Mo), aluminum (Al), chromium (Cr), gold (Au), titanium (Ti), nickel (Ni), neodymium (Nd), and/or copper (Cu), and/or an alloy thereof.

In one or more embodiments, the second source-drain conductive layer SD2 may include a data line DL, a second vertical power line V_VDL, and a second anode connection electrode (ANCE2 in FIG. 6).

The data line DL may extend in the second direction DR2. The data line DL may be electrically connected to the data connection electrode DCE through the source-drain contact hole CNH4 penetrating through the first passivation layer 143. As a result, the data line DL may be electrically connected to the second source region S2 of the second transistor T2.

In one or more embodiments, the data line DL may overlap the third power line VIL, the scan write line GWL, and the bias scan line GBL included in the first gate conductive layer CDL1, the fifth power line VOBL included in the second gate conductive layer CDL2, the scan initialization line GIL, the scan control line GCL, and the emission control line EML included in the third gate conductive layer CDL3, and the second horizontal power line HVDL and the fourth power line VAIL included in the first source-drain conductive layer SD1 in the third direction DR3.

In addition, the data line DL may overlap at least one of the first to eighth transistors T1 to T8 in the third direction DR3.

The second vertical power line V_VDL may extend in the second direction DR2. The second vertical power line V_VDL may be connected to the second horizontal power line HVDL through the source-drain contact hole CNH4.

In one or more embodiments, the second vertical power line V_VDL may overlap the third power line VIL, the scan write line GWL, and the bias scan line GBL included in the first gate conductive layer CDL1, the fifth power line VOBL included in the second gate conductive layer CDL2, the scan initialization line GIL, the scan control line GCL, and the emission control line EML included in the third gate conductive layer CDL3, and the second horizontal power line HVDL and the fourth power line VAIL included in the first source-drain conductive layer SD1 in the third direction DR3.

In addition, the second vertical power line V_VDL may overlap at least one of the first to eighth transistors T1 to T8 in the third direction DR3.

In one or more embodiments, the second vertical power line V_VDL may be disposed to pass through a portion overlapping the third contact hole CNH3.

The second anode connection electrode CNE2 may be electrically connected to the first anode connection electrode CNE1 through the fourth contact hole CNH4 penetrating through the first passivation layer 143.

In one or more embodiments, the first source-drain conductive layer SD1 and the second source-drain conductive layer SD2 may be positioned in a portion overlapping the valley area Valley.

The second passivation layer 145 may be located on the second source-drain conductive layer SD2 and on the first passivation layer 143. The second passivation layer 145 may entirely cover the second source-drain conductive layer SD2 and the first passivation layer 143.

The second passivation layer 145 may include an inorganic insulating material. Details will be described later.

As illustrated in FIG. 6, the display element layer DIL may be located on the thin film transistor layer TFTL. The display element layer DIL may include a via layer 151, a pixel defining layer 153, and a light emitting element LE.

The via layer 151 may be located on the thin film transistor layer TFTL. The via layer 151 may be in contact with the second passivation layer 145. The via layer 151 may planarize a step difference of a lower structure.

The via layer 151 may include an organic material. As an example, the via layer 151 may include an acrylic resin, a silicone resin, a silicone acrylic resin, an epoxy resin, polyimide, polyamide, benzocyclobutene, a phenol resin, etc.

In one or more embodiments, the via layer 151 may include a via opening OP1. The via layer 151 may be around (e.g., may surround) the via opening OP1. The via opening OP1 may refer to a portion where the via layer 151 does not overlap the thin film transistor layer TFTL. In other words, the via layer 151 may have an organic pattern shape.

The second passivation layer 145 according to one or more embodiments may be exposed at a portion overlapping the via opening OP1.

The display device 10 according to one or more embodiments is used in various electronic devices 1, and thus heat-resistant reliability in a high-temperature environment may be required. For example, the display device 10 according to one or more embodiments may be disposed in a vehicle into which a large amount of external light is incident. In this case, the display device 10 may be exposed to high temperatures for a long period of time, and thus heat-resistant reliability may be required.

In general, the thin film transistor layer may include a plurality of organic material layers that planarize the step differences of the plurality of conductive layers. For example, when the display device includes a plurality of stacked organic material layers, outgassing of the organic materials may occur in a high-temperature exposure environment. The outgassing of the organic materials may cause damage to the plurality of conductive layers included in the thin film transistor layer TFTL.

Accordingly, the display device 10 according to one or more embodiments aims to reduce or minimize the organic material layers included in the thin film transistor layer TFTL. As a result, in the display device 10 according to one or more embodiments, the first passivation layer 143 and the second passivation layer 145 included in the thin film transistor layer TFTL may be formed to include an inorganic insulating material, and the via layer 151 including the organic material may be patterned to include the via opening OP1.

In this way, the display device 10 according to one or more embodiments may reduce the organic material layer overlapping the plurality of conductive layers included in the thin film transistor layer TFTL, and may prevent the conductive layers from being damaged due to the outgassing of the organic material in the high-temperature exposure environment.

The light emitting element LE may be located on the via layer 151. The light emitting element LE may include an anode electrode AE, a light emitting layer EL, and a cathode electrode CE. The light emitting element LE refers to an element that emits light by the recombination of holes from the anode electrode AE and electrons from the cathode electrode CE in the light emitting layer EL. Each of the plurality of light emitting elements LE may be an organic light emitting diode (OLED) in which the light emitting layer EL is formed as an organic light emitting layer, but the present disclosure is not limited thereto.

The anode electrode AE may be located on the via layer 151. The anode electrode AE may have a flat shape as being on the via layer 151. The anode electrode AE may not overlap the via opening OP1.

The anode electrode AE may be electrically connected to the second anode connection electrode ANCE2 through an anode contact hole ACNH. The anode electrode AE may be connected to the sixth drain region D6 of the sixth transistor T6 through the second anode connection electrode ANCE2 and the first anode connection electrode ANCE1.

The anode electrode AE may have a stacked film structure in which a material layer having a high work function, such as indium tin oxide (ITO), indium zinc oxide (IZO), zinc oxide (ZnO), and/or indium oxide (In₂O₃) and a reflective material layer such as silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), and/or a mixture thereof are stacked. As an example, the anode electrode AE may have a multilayer structure of ITO/Mg, ITO/MgF, ITO/Ag, and ITO/Ag/ITO, but is not limited thereto.

The pixel defining layer 153 may be disposed on the anode electrode AE and the via layer 151 in a portion overlapping the non-light emitting area NLA. The pixel defining layer 153 may cover an edge of the anode electrode AE and may define a light emitting opening OP2. The light emitting area EA and the non-light emitting area NLA may be defined by the light emitting opening OP2.

The pixel defining layer 153 may assist in separating (e.g., insulating) the anode electrode AE and the cathode electrode CE from each other.

The pixel defining layer 153 may include an organic material. As an example, the pixel defining layer 153 may include an acrylic resin, a silicone resin, a silicone acrylic resin, an epoxy resin, polyimide, polyamide, benzocyclobutene, a phenol resin, etc.

In one or more embodiments, the via opening OP1 may be spaced (e.g., spaced apart) from the light emitting opening OP2. In other words, the via opening OP1 may not overlap the light emitting opening OP2.

The pixel defining layer 153 according to one or more embodiments may have an organic pattern shape so as not to overlap the via opening OP1 and the light emitting opening OP2. In other words, the pixel defining layer 153 may be positioned between the via opening OP1 and the light emitting opening OP2.

For example, when the pixel defining layer 153 is entirely formed on the thin film transistor layer TFTL, the organic material included in the pixel defining layer 153 may generate outgassing in a high temperature exposure environment, and the outgassing of the organic material may cause damage to the plurality of conductive layers included in the thin film transistor layer TFTL. The redundant descriptions will be omitted.

Accordingly, the display device 10 according to one or more embodiments may pattern the pixel defining layer 153 including the organic material, thereby reducing the organic material layer overlapping the plurality of conductive layers included in the thin film transistor layer TFTL, and prevent the conductive layers from being damaged due to the outgassing of the organic material in the high-temperature exposure environment.

The light emitting layer EL may be located on the anode electrode AE and the pixel defining layer 153. The light emitting layer EL may be in contact with the anode electrode AE at a portion overlapping the light emitting opening OP2.

Each of the light emitting layers EL may include an organic material and emit light. For example, the light emitting layer EL of the first light emitting area EA1 may emit first light, the light emitting layer EL of the second light emitting area EA2 may emit second light, and the light emitting layer EL of the third light emitting area EA3 may emit third light (e.g., see FIG. 4 and FIG. 6). Each of the light emitting layers EL may include a hole transporting layer, an organic material layer, and an electron transporting layer.

The cathode electrode CE may be disposed on the light emitting layer EL and the pixel defining layer 153. The cathode electrode CE may be in contact with and entirely cover the light emitting layer EL and the pixel defining layer 153.

In addition, the cathode electrode CE according to one or more embodiments may be in contact with and cover the second passivation layer 145 at a portion overlapping the via opening OP1.

In the top emission structure, the cathode electrode CE may include a transparent conductive material (TCO) such as ITO and/or IZO capable of transmitting light, or a semi-transmissive conductive material such as magnesium (Mg), silver (Ag), and/or an alloy of magnesium (Mg) and silver (Ag). When the cathode electrode CE includes the semi-transmissive conductive material, light emitting efficiency of each of the light emitting element LE may be increased by a micro cavity.

In one or more embodiments, an encapsulation layer that includes at least one inorganic insulating material and prevents the permeation of oxygen and/or moisture, a polarizing film for preventing degradation in visibility due to external light, or sensor electrodes for sensing touches may also be disposed on the display element layer DIL.

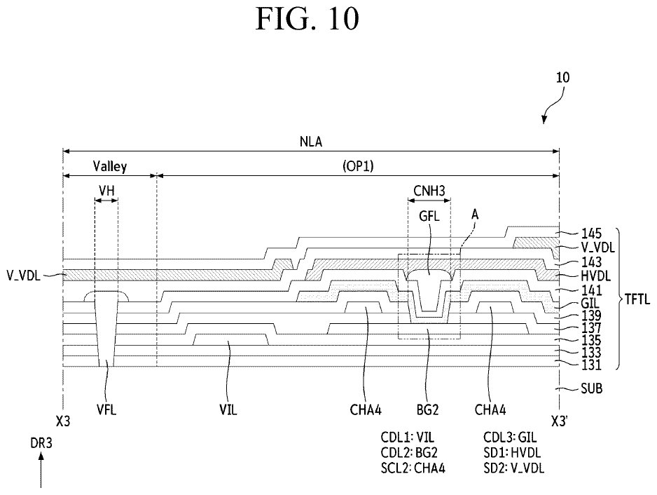

FIG. 10 is a cross-sectional view taken along the line X3-X3′ in FIG. 5. FIG. 10 illustrates an example of a substrate and a thin film transistor layer cut along the line X3-X3′ in FIG. 5.

Referring to FIG. 10 in addition to FIG. 1-9, the display device 10 according to one or more embodiments may include a via opening OP1 and a valley area Valley located in a portion overlapping the non-light emitting area NLA.

The third power line VIL included in the first gate conductive layer CDL1 may be located on the first gate insulating layer 133 in a portion overlapping the non-light emitting area NLA. The third power line VIL included in the first gate conductive layer CDL1 may be located in a portion overlapping the via opening OP1.

The second lower electrode BG2 included in the second gate conductive layer CDL2 may be located on the second gate insulating layer 135 in a portion overlapping the non-light emitting area NLA. The second lower electrode BG2 included in the second gate conductive layer CDL2 may be located in a portion overlapping the via opening OP1.

The second lower electrode BG2 may overlap the fourth channel region CHA4 included in the second semiconductor layer SCL2 in the third direction DR3.

The scan initialization line GIL included in the third gate conductive layer CDL3 may be located on the third gate insulating layer 139 in a portion overlapping the non-light emitting area NLA. The scan initialization line GIL included in the third gate conductive layer CDL3 may be located in a portion overlapping the via opening OP1.

In one or more embodiments, the second lower electrode BG2 included in the second gate conductive layer CDL2 may be connected to the scan initialization line GIL included in the third gate conductive layer CDL3 through the gate contact hole CNH3. The second lower electrode BG2 may be utilized as a back gate electrode of the fourth transistor T4 as being connected to the scan initialization line GIL.

The data contact hole CNH3 may penetrate through the first interlayer insulating layer 137 and the third gate insulating layer 139. The gate contact hole CNH3 may assist in connecting the third gate conductive layer CDL3 with at least one of the first gate conductive layer CDL1 or the second gate conductive layer CDL2.

The second interlayer insulating layer 141 may entirely cover the third gate conductive layer CDL3. The second interlayer insulating layer 141 may be in contact with and cover the scan initialization line GIL included in the third gate conductive layer CDL3 in a portion overlapping the gate contact hole CNH3.

A gate flat layer GFL may be positioned on the second interlayer insulating layer 141. The gate flat layer GFL may be positioned in (e.g., within) the gate contact hole CNH3. The gate flat layer GFL may be an organic pattern in the form of an island.

The gate flat layer GFL may include an organic material. As an example, the gate flat layer GFL may include an acrylic resin, a silicone resin, a silicone acrylic resin, an epoxy resin, polyimide, polyamide, benzocyclobutene, a phenol resin, etc.

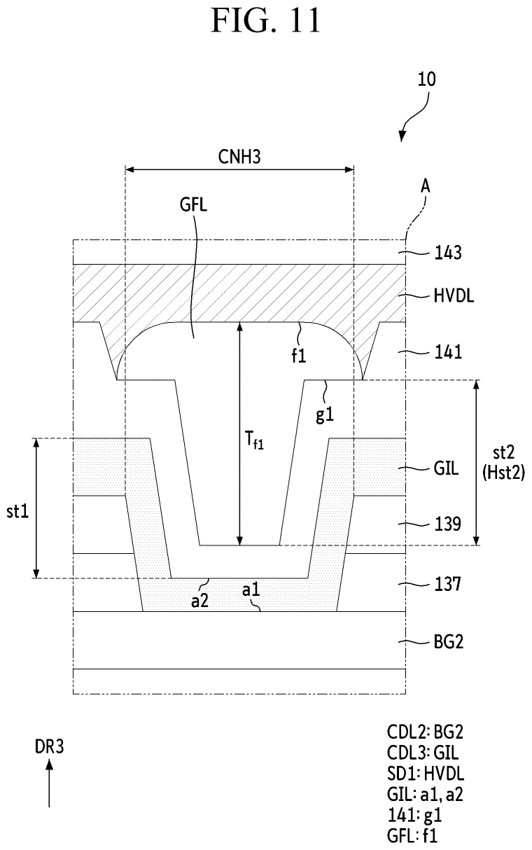

FIG. 11 is an enlarged cross-sectional view of an area ‘A’ in FIG. 10.

Referring to FIGS. 10 and 11 in addition to FIG. 1-9, in one or more embodiments, the scan initialization line GIL included in the third gate conductive layer CDL3 may be formed with a uniform thickness along a profile of the lower structure in a portion overlapping the gate contact hole CNH3. The above-mentioned uniform thickness may include a process error range of 5% or less.

Accordingly, the scan initialization line GIL included in the third gate conductive layer CDL3 may include a step difference st1 in a portion overlapping the gate contact hole CNH3.

The scan initialization line GIL included in the third gate conductive layer CDL3 may be in contact with and cover a side surface of the first interlayer insulating layer 137 and a side surface of the third gate insulating layer 139 facing the gate contact hole CNH3 in a portion overlapping the gate contact hole CNH3.

In one or more embodiments, the scan initialization line GIL included in the third gate conductive layer CDL3 may include an upper surface a2 and a lower surface a1. The upper surface a2 of the scan initialization line GIL may be in contact with the second interlayer insulating layer 141, and the lower surface a1 thereof may be in contact with the second gate conductive layer CDL2.

In one or more embodiments, the second interlayer insulating layer 141 may be formed with a uniform thickness along the profile of the lower structure. Accordingly, the second interlayer insulating layer 141 may include a step difference st2 in a portion overlapping the gate contact hole CNH3.

The second interlayer insulating layer 141 may cover the side surface of the first interlayer insulating layer 137 and the side surface of the third gate insulating layer 139 facing the gate contact hole CNH3 so as to be spaced (e.g., spaced apart) from the side surfaces.

The second interlayer insulating layer 141 may include an upper surface g1. The upper surface g1 of the second interlayer insulating layer 141 may be in contact with the gate flat layer GFL.

The gate flat layer GFL may be spaced (e.g., spaced apart) from the third gate conductive layer CDL3 with the second interlayer insulating layer 141 interposed therebetween.

The gate flat layer GFL may planarize the step difference st2 included in the second interlayer insulating layer 141 in a portion overlapping the third contact hole CNH3. Accordingly, the gate flat layer GFL may assist the first source-drain conductive layer SD1 to have a flat surface in the portion overlapping the third contact hole CNH3. Details will be described later.

The gate flat layer GFL may cover the side surface of the first interlayer insulating layer 137, the side surface of the third gate insulating layer 139, and the upper surface a2 of the third gate conductive layer CDL3 facing the gate contact hole CNH3.

In one or more embodiments, a thickness T_{f1} of the gate flat layer GFL may have a value greater than a height Hst2 of a step difference st2 of the second interlayer insulating layer 141.

In one or more embodiments, the second horizontal power line HVDL included in the first source-drain conductive layer SD1 may be located on the second interlayer insulating layer 141 and the gate flat layer GFL in a portion overlapping the non-light emitting area NLA. The second horizontal power line HVDL included in the first source-drain conductive layer SD1 may be located in a portion overlapping the via opening OP1.

In one or more embodiments, the second horizontal power line HVDL included in the first source-drain conductive layer SD1 may be located in a portion overlapping the third contact hole CNH3 and may have a flat surface.

The display device 10 according to one or more embodiments is used in various electronic devices 1, and thus high resolution characteristics may be required. This may mean that the plurality of conductive layers are disposed at a high density in directions parallel and perpendicular to one surface of the substrate SUB in (e.g., within) a narrow area. As a result, the contact hole of the display device applied to the high-resolution electronic device may have a narrow and deep width.

For example, when conductive lines including source-drain conductive layers are formed to be overlapped with each other in the portion overlapping the contact hole, the conductive lines included in the source-drain conductive layers may include a narrow and deep step difference, which may cause short circuit defects in the conductive lines. In addition, when the conductive lines included in the source-drain conductive layers include the narrow and deep step difference, a defect may occur in which the conductive lines are not insulated from the lower conductive layers and come into contact with the lower conductive lines.

Accordingly, a design may be required in which the conductive lines included in the source-drain conductive layers of the display device applied to the high-resolution electronic device are formed by bypassing or avoiding the plurality of contact holes. This may increase the manufacturing difficulty of the display device and reduce area efficiency.

Therefore, as the display device 10 according to one or more embodiments includes the gate flat layer GFL in the portion overlapping the gate contact hole CNH3, the conductive lines included in the first source-drain conductive layer SD1 may be formed to include the flat surface, and in addition, it may assist in insulating the first source-drain conductive layer SD1 from the third gate conductive layer CDL3 therebelow.

In other words, even if the display device 10 according to one or more embodiments is applied to the high-resolution electronic device 1, the conductive lines included in the first source-drain conductive layer SD1 may be formed to overlap the gate contact hole CNH3 without avoiding the gate contact hole CNH3.

In addition, even if the display device 10 according to one or more embodiments is applied to the high-resolution electronic device 1, the conductive lines included in the first source-drain conductive layer SD1 may be insulated from the plurality of lower conductive layers.

As a result, the display device 10 according to one or more embodiments may have ease of manufacturing, increase area efficiency, and resolve reliability problems.

The gate flat layer GFL according to one or more embodiments may be in contact with the second interlayer insulating layer 141 and the first source-drain conductive layer SD1.

In one or more embodiments, the gate flat layer GFL may be entirely surrounded by the second interlayer insulating layer 141 and the first source-drain conductive layer SD1.

As illustrated in FIG. 10, the second vertical power line V_VDL included in the second source-drain conductive layer SD2 may be on the first passivation layer 143 in a portion overlapping the non-light emitting area NLA. The second vertical power line V_VDL included in the second source-drain conductive layer SD2 may be in a portion overlapping the via opening OP1. In addition, the second vertical power line V_VDL included in the second source-drain conductive layer SD2 may be in a portion overlapping the valley area Valley.

The display device 10 according to one or more embodiments may include a valley flat layer VFL in a portion overlapping the valley area Valley. The valley flat layer VFL may entirely fill a valley hole VH formed in the portion overlapping the valley area Valley. The valley flat layer VFL may be in contact with and may be covered by the first passivation layer 143.

The valley hole VH according to one or more embodiments may be formed to penetrate through the buffer layer 131, the first gate insulating layer 133, the second gate insulating layer 135, the first interlayer insulating layer 137, the third gate insulating layer 139, and the second interlayer insulating layer 141 (e.g., see FIG. 10), but is not limited thereto. According to one or more embodiments, the valley hole VH may penetrate through the third gate insulating layer 139, and in addition, may be formed to penetrate through at least one of the buffer layer 131, the first gate insulating layer 133, the second gate insulating layer 135, or the first interlayer insulating layer 137.

The valley flat layer VFL may include the same material as the gate flat layer GFL. The valley flat layer VFL may be formed in the same process as the gate flat layer GFL in the process of manufacturing the display device 10. Accordingly, the display device 10 may have ease of manufacturing.

The valley flat layer VFL may protect the plurality of conductive layers included in the thin film transistor layer TFTL from physical shock.

In one or more embodiments, the valley flat layer VFL may overlap the gate flat layer GFL in a direction parallel to the substrate SUB.

The second vertical power line V_VDL included in the second source-drain conductive layer SD2 may overlap the valley flat layer VFL in the third direction DR3 in a portion overlapping the valley area Valley.

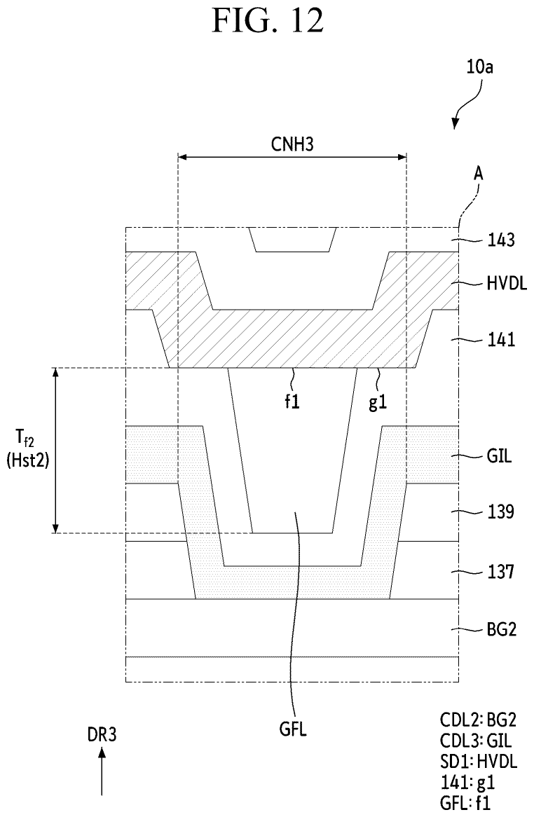

FIG. 12 is an enlarged cross-sectional view of the area ‘A’ of FIG. 10 according to one or more other embodiments.

Referring to FIG. 12 in addition to FIG. 1-11, an upper surface f1 of a gate flat layer GFL included in a display device 10a may be on the same line (e.g., collinear) as an upper surface g1 of a second interlayer insulating layer 141.

The gate flat layer GFL included in the display device 10a may planarize a step difference Hst2 included in the second interlayer insulating layer 141 in a portion overlapping the third contact hole CNH3. A thickness T_{f2} of the gate flat layer GFL included in the display device 10a may have the same value as the height Hst2 of the step difference of the second interlayer insulating layer 141. The meaning of the same value as described above may include a range of process error of 5% or less.

The gate flat layer GFL included in the display device 10a may be formed by additionally performing a planarization process after a process of forming the gate flat layer GFL in the manufacturing process.

The gate flat layer GFL may assist the second horizontal power line HVDL included in the first source-drain conductive layer SD1 to include a relatively lower step difference than the step difference Hst2 included in the second interlayer insulating layer 141 in a portion overlapping the third contact hole CNH3. The redundant descriptions will be omitted.

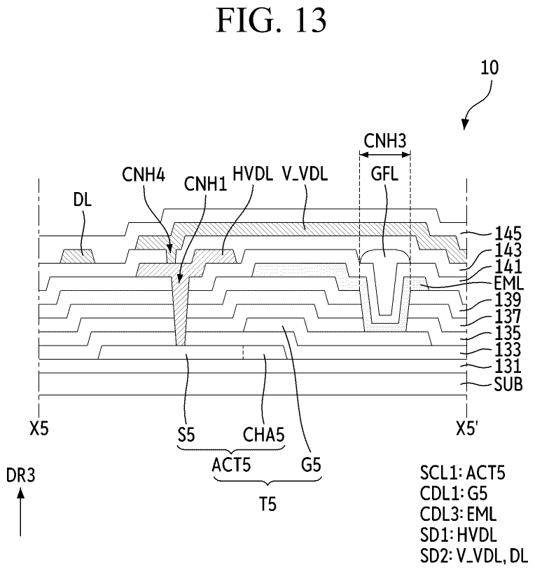

FIG. 13 is a cross-sectional view taken along the line X5-X5′ in FIG. 5.

Referring to FIG. 13 in addition to FIG. 1-12, in one or more embodiments, the fifth active layer ACT5 included in the first semiconductor layer SCL1 may be located on the buffer layer 131. A fifth channel region CHA5 included in the fifth active layer ACT5 may overlap the fifth gate electrode G5 included in the first gate conductive layer CDL1.

A fifth source region S5 included in the fifth active layer ACT5 may be connected to the second horizontal power line HVDL included in the first source-drain conductive layer SD1 through the first contact hole CNH1, and the second horizontal power line HVDL may be connected to the second vertical power line V_VDL included in the second source-drain conductive layer SD2 through the source-drain contact hole CNH4.

The emission control line EML included in the third gate conductive layer CDL3 may be positioned on the third gate insulating layer 139.

The emission control line EML included in the third gate conductive layer CDL3 may be connected to the fifth gate electrode G5 included in the first gate conductive layer CDL1 in a portion overlapping the gate contact hole CNH3. Accordingly, the emission control line EML may include a step difference in the portion overlapping the gate contact hole CNH3. The redundant descriptions will be omitted.

The second interlayer insulating layer 141 may entirely cover the emission control line EML included in the third gate conductive layer CDL3. The second interlayer insulating layer 141 may include a step difference st2 in a portion overlapping the third contact hole CNH3. The redundant descriptions will be omitted.

The second interlayer insulating layer 141 may be spaced (e.g., spaced apart) from the first gate conductive layer CDL1 with the third gate conductive layer CDL3 interposed therebetween in a portion overlapping the third contact hole CNH3.

A gate flat layer GFL may be on the second interlayer insulating layer 141. The gate flat layer GFL may be an organic pattern in the form of an island. The gate flat layer GFL may planarize the step difference included in the second interlayer insulating layer 141 in a portion overlapping the third contact hole CNH3. The redundant descriptions will be omitted.

In one or more embodiments, the gate flat layer GFL may be in contact with the second interlayer insulating layer 141 and the first passivation layer 143, and may be entirely surrounded by the second interlayer insulating layer 141 and the first passivation layer 143.

The second vertical power line V_VDL included in the second source-drain conductive layer SD2 may be on the first passivation layer 143. The second vertical power line V_VDL included in the second source-drain conductive layer SD2 may be in a portion overlapping the gate contact hole CNH3 and may overlap the gate flat layer GFL.

The second vertical power line V_VDL included in the second source-drain conductive layer SD2 may include a flat surface in a portion overlapping the gate contact hole CNH3.

As the display device 10 according to one or more embodiments includes the gate flat layer GFL in the portion overlapping the gate contact hole CNH3, the conductive lines included in the second source-drain conductive layer SD2 may be formed to include the flat surface, and it may assist in insulating the second source-drain conductive layer SD2 from the third gate conductive layer CDL3 therebelow.

In other words, even if the display device 10 according to one or more embodiments is applied to the high-resolution electronic device 1, the conductive lines included in the second source-drain conductive layer SD2 may be formed to overlap the gate contact hole CNH3 without avoiding the gate contact hole CNH3.

In addition, even if the display device 10 according to one or more embodiments is applied to the high-resolution electronic device 1, the conductive lines included in the second source-drain conductive layer SD2 may be insulated from the plurality of lower conductive layers. As a result, the display device 10 according to one or more embodiments may have ease of manufacturing, increase area efficiency, and resolve reliability problems.

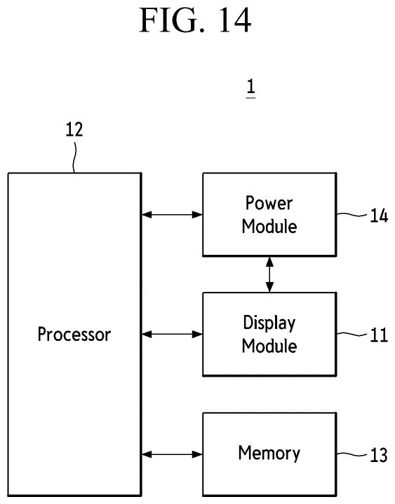

FIG. 14 is a block diagram of an electronic device according to one or more embodiments.

Referring to FIG. 14 in addition to FIG. 1-13, the display device 10 according to one or more embodiments may be applied to various electronic devices 1. The electronic device 1 according to one or more embodiments may include the display device 10 described above, and may further include a module or device having additional functions in addition to the display device 10.

The electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included in (e.g., within) one module may be included in (e.g., within) the display device, while others may be provided separately from the display device. For example, the display device includes the display module 11, and the processor 12, the memory 13, and the power module 14 may be provided in the form of other devices in (e.g., within) the electronic device 1 other than the display device.

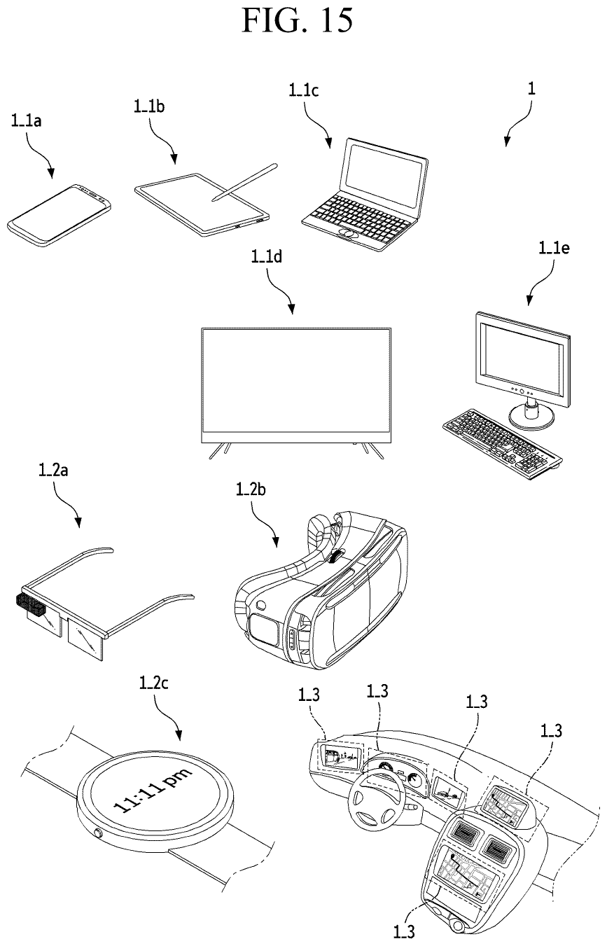

FIG. 15 illustrates schematic diagrams of electronic devices according to various embodiments.

Referring to FIG. 15, various electronic devices 1 to which the display device 10 according to one or more embodiments is applied may include not only an image display electronic device such as a smart phone 1_1a, a tablet PC 1_1b, a laptop 1_1c, a TV 1_1d, and a desk monitor 1_1e, but also a wearable electronic device including a display module such as a smart glasses 1_2a, a head mounted display 1_2b, a smart watch 1_2c, and/or the like, and a vehicle electronic device 1_3 including a display module such as a Center Information Display (CID), a room mirror display, etc., disposed on a vehicle's instrument panel, center fascia, and/or dashboard.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation. The scope of the present disclosure is represented by the scope of the accompanying claims, rather than the detailed description. All changes or modifications derived from the meaning and scope of the claims and equivalent concepts thereof should be interpreted as being included in the scope of the present disclosure.

Although the embodiments of the present disclosure have been described with reference to the accompanying drawings, it will be apparent to those skilled in the art that the present disclosure can be embodied in other specific forms without departing from the technical spirits and essential characteristics. Thus, the above embodiments are to be considered in all respects as illustrative and not restrictive.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

Features of various embodiments of the present disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the principles and scope of the present disclosure. Therefore, the embodiments of the present disclosure are used in a generic and descriptive sense and not for purposes of limitation.

What is claimed is:

1. A display device comprising:
a substrate including a light emitting area and a non-light emitting area;
a first gate conductive layer and a second gate conductive layer on the substrate and sequentially stacked;
a third gate conductive layer on the second gate conductive layer and in contact with at least one of the first gate conductive layer or the second gate conductive layer through a gate contact hole;
an interlayer insulating layer on the third gate conductive layer;
a source-drain conductive layer on the interlayer insulating layer;
a gate flat layer between the interlayer insulating layer and the source-drain conductive layer and located in the gate contact hole; and
a passivation layer on the source-drain conductive layer,
wherein the gate flat layer has an organic pattern shape, and
wherein, in a portion overlapping the gate contact hole, the source-drain conductive layer overlaps the gate flat layer.

2. The display device of claim 1, further comprising:
a via layer on the passivation layer and defining a via opening;
a light emitting element on the via layer, the light emitting element comprising an anode electrode, a light emitting layer, and a cathode electrode; and
a pixel defining layer on the anode electrode and defining a light emitting opening defining the light emitting area and the non-light emitting area,
wherein, in a portion overlapping the light emitting opening, the anode electrode is in contact with the light emitting layer, and
wherein, in a portion overlapping the via opening, the passivation layer is exposed.

3. The display device of claim 2, wherein the light emitting opening and the via opening are spaced from each other,
wherein the pixel defining layer does not overlap the via opening, and
wherein the pixel defining layer has an organic pattern shape.

4. The display device of claim 3, wherein the gate flat layer and the third gate conductive layer overlapping the gate contact hole overlap the via opening.

5. The display device of claim 2, wherein the source-drain conductive layer comprises a first source-drain conductive layer and a second source-drain conductive layer that are sequentially stacked, and
wherein, in a plan view, the first source-drain conductive layer and the second source-drain conductive layer overlap the gate contact hole.

6. The display device of claim 5, wherein the gate flat layer is in contact with the first source-drain conductive layer, and
wherein the gate flat layer is entirely surrounded by the interlayer insulating layer and the first source-drain conductive layer.

7. The display device of claim 6, wherein the first source-drain conductive layer comprises at least one of a data connection electrode, a power line, or a connection electrode.

8. The display device of claim 5, wherein the passivation layer comprises:
a first passivation layer located between the gate flat layer and the second source-drain conductive layer; and
a second passivation layer covering the second source-drain conductive layer,
wherein the gate flat layer is in contact with the interlayer insulating layer and the first passivation layer, and
wherein the gate flat layer is entirely surrounded by the interlayer insulating layer and the first passivation layer.

9. The display device of claim 8, wherein the second source-drain conductive layer comprises at least one of a data electrode or a power line.

10. The display device of claim 8, wherein the first passivation layer and the second passivation layer comprise an inorganic insulating material.

11. The display device of claim 2, further comprising:
a first semiconductor layer located between the substrate and the first gate conductive layer and comprising a source region, a channel region, and a drain region; and
a second semiconductor layer located between the second gate conductive layer and the third gate conductive layer,
wherein the source-drain conductive layer is connected to at least one of the first semiconductor layer or the second semiconductor layer.

12. The display device of claim 11, wherein the first semiconductor layer comprises polysilicon, and
wherein the second semiconductor layer comprises an oxide semiconductor.

13. The display device of claim 2, wherein in the portion overlapping the gate contact hole, the interlayer insulating layer includes a step difference, and a thickness of the gate flat layer is greater than or equal to a height of the step difference in the interlayer insulating layer.

14. The display device of claim 13, wherein the gate flat layer is spaced from the third gate conductive layer, and
wherein the gate flat layer is in contact with and covers a portion of an upper surface of the interlayer insulating layer facing the source-drain conductive layer.

15. An electronic device comprising:
at least one display device comprising a substrate including a light emitting area and a non-light emitting area; and
at least one of a display module, a processor, a memory, or a power module connected to the display device,
wherein the display device comprises:
a first gate conductive layer and a second gate conductive layer on the substrate and sequentially stacked;
a third gate conductive layer on the second gate conductive layer and in contact with at least one of the first gate conductive layer or the second gate conductive layer through a gate contact hole;
an interlayer insulating layer on the third gate conductive layer;
a source-drain conductive layer on the interlayer insulating layer;
a gate flat layer between the interlayer insulating layer and the source-drain conductive layer and located in the gate contact hole; and
a passivation layer on the source-drain conductive layer,
wherein the gate flat layer has an organic pattern shape, and
wherein, in a portion overlapping the gate contact hole, the source-drain conductive layer overlaps the gate flat layer.

16. The electronic device of claim 15, wherein the display device further comprises:
a via layer on the passivation layer and defining a via opening;
a light emitting element on the via layer, the light emitting element comprising an anode electrode, a light emitting layer, and a cathode electrode; and
a pixel defining layer on the via layer and defining a light emitting opening defining the light emitting area and the non-light emitting area,
wherein, in a portion overlapping the light emitting opening, the anode electrode is in contact with the light emitting layer, and
wherein, in a portion overlapping the via opening, the passivation layer is exposed.

17. The electronic device of claim 16, wherein the gate flat layer and the third gate conductive layer overlapping the gate contact hole overlap the via opening.

18. The electronic device of claim 16, wherein the source-drain conductive layer comprises a first source-drain conductive layer and a second source-drain conductive layer that are sequentially stacked, and
wherein, in a plan view, the first source-drain conductive layer and the second source-drain conductive layer overlap the gate contact hole.

19. The electronic device of claim 18, wherein the gate flat layer is in contact with the first source-drain conductive layer,
wherein the gate flat layer is entirely surrounded by the interlayer insulating layer and the first source-drain conductive layer, and
wherein the first source-drain conductive layer comprises at least one of a data connection electrode, a power line, or a connection electrode.

20. The electronic device of claim 18, wherein the passivation layer comprises:
a first passivation layer located between the gate flat layer and the second source-drain conductive layer; and
a second passivation layer covering the second source-drain conductive layer,
wherein the gate flat layer is in contact with the interlayer insulating layer and the first passivation layer,
wherein the gate flat layer is entirely surrounded by the interlayer insulating layer and the first passivation layer,
wherein the second source-drain conductive layer comprises at least one of a data electrode or a power line, and
wherein the first passivation layer and the second passivation layer comprise an inorganic insulating material.
